(19) United States
(12) Patent Application Publication
(10) Pub. No.: US 2026/0136547 A1
(43) Pub. Date: May 14, 2026

(54) SEMICONDUCTOR STRUCTURE, METHOD FOR FORMING THE SEMICONDUCTOR STRUCTURE AND INSPECTION METHOD

(71) Applicant: Winbond Electronics Corp., Taichung City (TW)

(72) Inventor: Chang-Hung LIN, Chiayi City (TW)

(21) Appl. No.: 19/380,237

(22) Filed: Nov. 5, 2025

(30) Foreign Application Priority Data
Nov. 12, 2024 (TW) 113143361

(51) Int. Cl. H10B 12/00; G01N 21/95; H01L 21/66

(52) U.S. Cl. CPC H10B 12/50; G01N 21/9501; H10B 12/09; H10B 12/34; H10B 12/485; H10P 74/273

(57) ABSTRACT

A semiconductor structure is provided. The semiconductor structure includes a first active region in a first region of a semiconductor substrate, a first gate electrode in the first active region, and a first dielectric capping layer disposed over the first gate electrode. The first gate electrode includes a first work function layer, a second work function layer over the first work function layer, a first barrier layer between the first and second work function layers, and a metal capping layer over the second work function layer.

### CROSS REFERENCE TO RELATED APPLICATIONS

This Application claims priority of Taiwan Patent Application No. 113143361, filed on November 12, 2024, the entirety of which is incorporated by reference herein.

### BACKGROUND OF THE DISCLOSURE

### Field of the Disclosure

The present disclosure relates to a semiconductor structure, and in particular, it relates to a dynamic random access memory having a test element group and a method for forming the same.

### Description of the Related Art

In order to enhance product yield in the semiconductor industry, inspections are performed on features of products while they are on the production line during the manufacturing process, to ensure that they meet specifications. Based on the results of these inspections, the process parameters may be adjusted in real time, so that the products may have a stable performance. With the scaling-down of semiconductor memory devices, inspection techniques are also facing more challenges. Therefore, there remains a need in the industry to improve the inspection methods of semiconductor memory devices and the test element groups used therein.

### BRIEF SUMMARY OF THE DISCLOSURE

Embodiments of the present disclosure provide a semiconductor structure. This semiconductor structure includes a first active region in a first region of a semiconductor substrate, a first gate electrode in the first active region, and a first dielectric capping layer disposed over the first gate electrode. The first gate electrode includes a first work function layer, a second work function layer over the first work function layer, a first barrier layer between the first work function layer and the second work function layer, and a metal capping layer over the second work function layer.

Embodiments of the present disclosure provide a method for forming a semiconductor structure. This method includes forming a first active region and a second active region, forming a first trench in the first active region and a second trench in the second active region, forming a first work function layer in the first trench and the second trench, forming a second work function layer over the first work function layer in the first trench and the second trench, forming a metal material over the second work function layer in the first trench and the second trench, and removing a first portion of the metal material in the first trench. A second portion of the metal material remaining in the second trench forms a metal capping layer. This method further includes forming a first dielectric capping layer over the first work function layer in the first trench and forming a second dielectric capping layer over the metal capping layer in the second trench.

Embodiments of the present disclosure provide an inspection method. The detection method includes receiving a semiconductor structure. The semiconductor structure includes test regions and functional circuit regions disposed over a semiconductor substrate. Each of the test regions and each of the functional circuit regions includes a gate electrode embedded in the semiconductor substrate, a dielectric capping layer disposed over the gate electrode and partially embedded in the semiconductor substrate, and an opening over the semiconductor substrate exposing a sidewall of the dielectric capping layer. The gate electrode includes a first work function layer, a second work function layer over the first work function layer, and a barrier layer between the first work function layer and the second work function layer. The detection method further includes performing an imaging operation on the test regions of the semiconductor structure to generate a surface defect distribution map. The surface defect distribution map has information indicating whether a void exists between the dielectric capping layer and the second work function layer. The detection method further includes performing a determination operation on the surface defect distribution map to determine whether the depths of the openings in the functional circuit regions exceed an expected value.

### BRIEF DESCRIPTION OF THE DRAWINGS

The present disclosure can be more fully understood by reading the subsequent detailed description and examples with references made to the accompanying drawings, wherein:

FIG. 1 is a top view of a semiconductor structure according to some embodiments of the present disclosure;

FIGS. 2 to 12 are cross-sectional views of forming a semiconductor structure at various stages according to some embodiments of the present disclosure; and

FIGS. 13 and 14 are cross-sectional views of forming a semiconductor structure at various stages according to other embodiments of the present disclosure.

### DETAILED DESCRIPTION OF THE DISCLOSURE

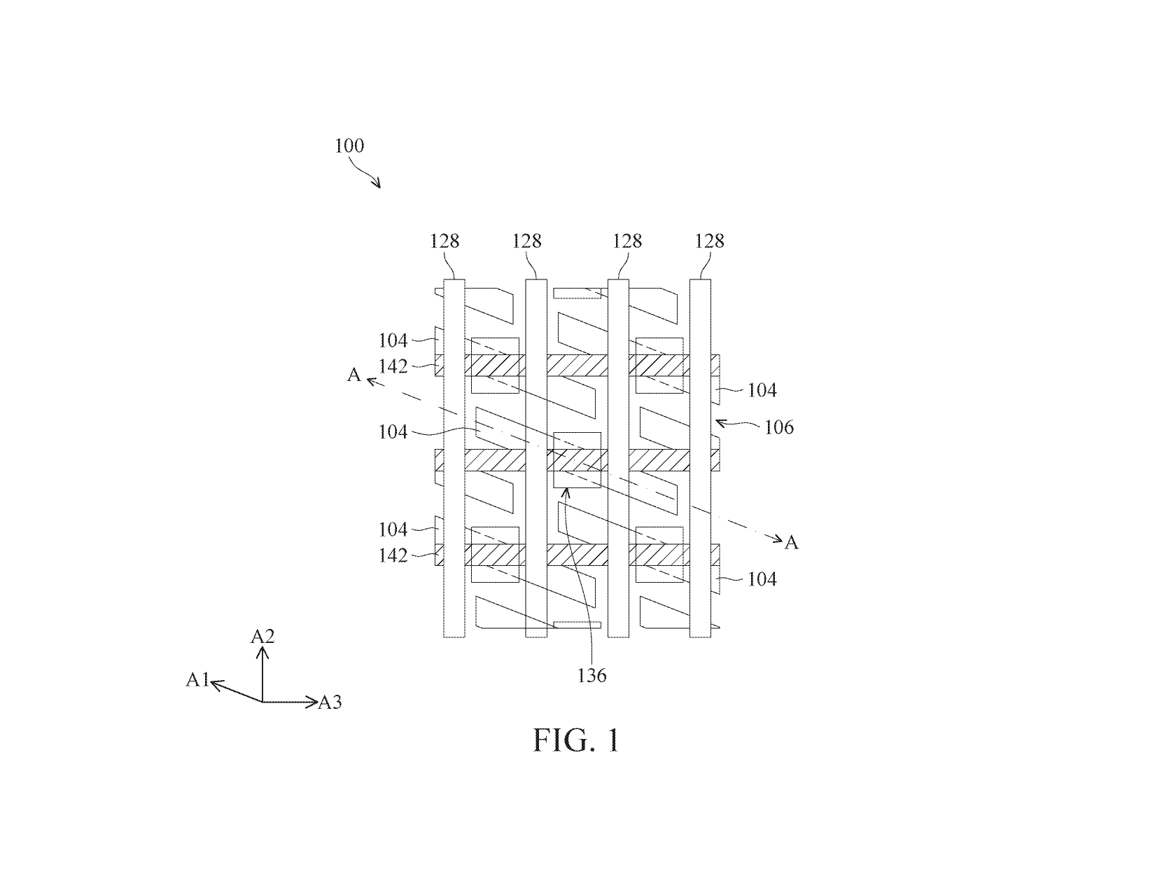

FIG. 1 is a top view of a semiconductor structure 100 according to some embodiments of the present disclosure. The semiconductor structure 100 is used to form a semiconductor memory device, such as a dynamic random access memory (DRAM). The semiconductor structure 100 includes active regions 104, isolation structure 106, gate electrodes 128, and wiring structures 142. The direction A1, direction A2, and direction A3 are horizontal directions, wherein the first direction A1 is a channel extension direction, the second direction A2 is a word line extension direction, and the third direction A3 is a bit line extension direction. The first direction A1 and the second direction A2 form an acute angle, ranging from about 10 degrees to about 80 degrees, for example. The second direction A2 is substantially perpendicular to the third direction A3.

The active region 104 is a semiconductor island extending along the first direction A1. In the second direction A2, adjacent active regions 104 are staggered. For example, the active regions 104 may be periodically aligned in the second direction A2 at intervals of every two active regions 104. Each active region 104 may include or be defined as a first source/drain region at a center of the semiconductor island, two second source/drain regions at opposite ends of the semiconductor island, and two channel regions between the first source/drain region and the second source/drain regions. The isolation structure 106 surrounds and electrically isolates the active region 104.

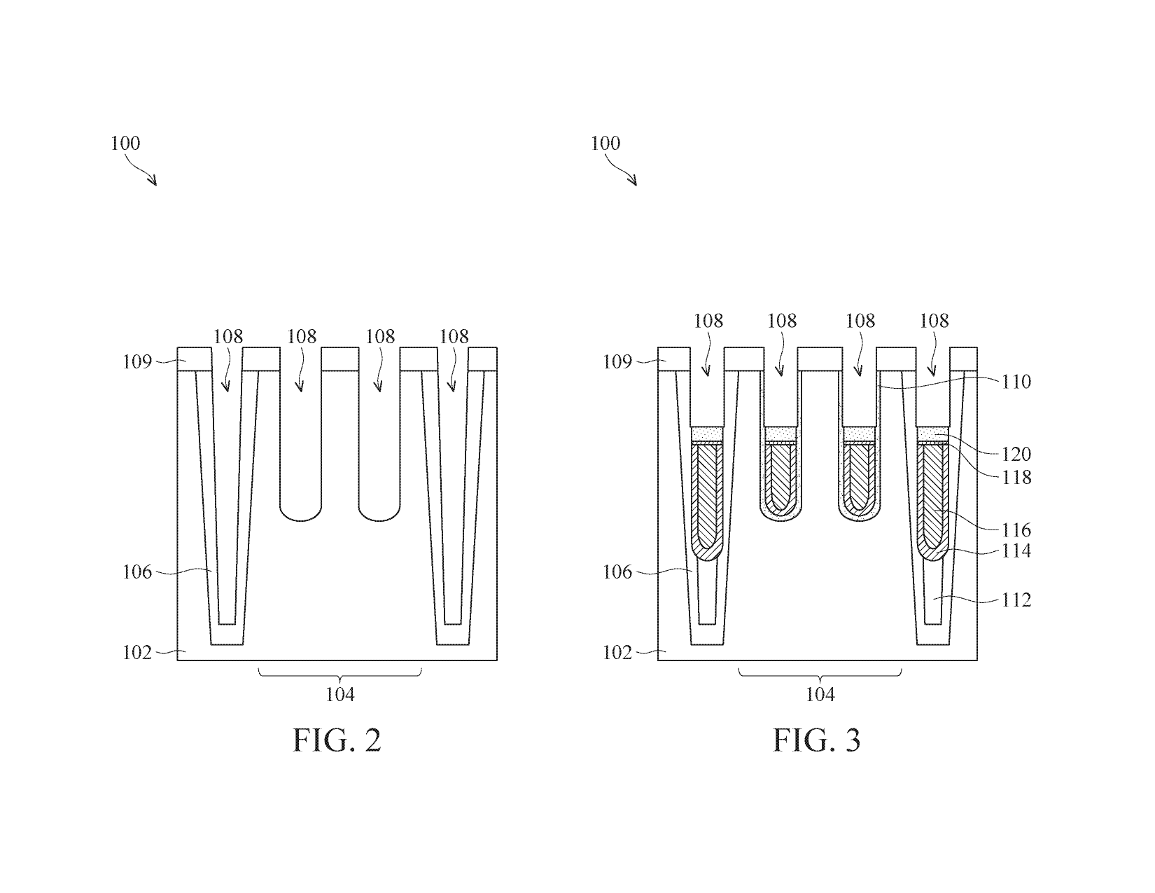

The gate electrodes 128 extend along the second direction A2, passing through the channel regions of the active regions 104 and the isolation structure 106. The semiconductor structure 100 may include an opening pattern 136, which extends into the first source/drain regions of the active region 104 and the adjacent isolation structure 106. The wiring structures 142 are formed over the active regions 104 and extend along the third direction A3. A portion of the wiring structure 142 filling into the opening patterns 136 may serve as a contact portion to electrically connect to the first source/drain region of the active region 104. For clarity of the drawing, FIG. 1 only shows the above features, and other features of the semiconductor structure 100 can be seen in the cross-sectional views of FIGS. 2 to 12.

FIGS. 2 to 12 are cross-sectional views illustrating the formation of the semiconductor structure 100 corresponding to cross-section A-A in FIG. 1 at various stages according to some embodiments of the present disclosure. The cross-section A-A is parallel to the first direction A1 and passes through the active region 104. Referring to FIG. 2, a semiconductor substrate 102 is provided. In some embodiments, the semiconductor substrate 102 is an elemental semiconductor substrate, such as a silicon substrate or a germanium substrate, or a compound semiconductor substrate, such as a silicon carbide substrate or a gallium arsenide substrate. In some embodiments, the semiconductor substrate 102 may be a semiconductor-on-insulator (SOI) substrate. The semiconductor substrate 102 may be a wafer including multiple die regions or a portion of a wafer.

The active region 104 is formed over the substrate 102. The formation of the active region 104 includes performing a first patterning process over the semiconductor substrate 102 to form semiconductor stripes extending in the first direction A1, and then performing a second patterning process to cut each of the semiconductor stripe into separate semiconductor islands. The patterning process may include a lithography process and an etching process.

Next, the isolation structure 106 is formed to surround the active region 104. In some embodiments, the isolation structure 106 is formed of a dielectric material, such as silicon oxide (SiO), silicon nitride (SiN), silicon oxynitride (SiON), and/or combinations thereof. The formation of the isolation structure 106 may use chemical vapor deposition (CVD) and/or atomic layer deposition (ALD) to deposit the dielectric material. A planarization process, such as etch-back and/or chemical mechanical polishing (CMP), is then performed on the dielectric material.

A dielectric layer 109 is formed over the semiconductor structure 100. In some embodiments, the dielectric layer 109 is made of a dielectric material, such as silicon oxide (SiO), silicon nitride (SiN), silicon oxynitride (SiON), and/or combinations thereof. Next, a patterning process is performed on the semiconductor structure 100 to form trenches 108 for the gate electrodes 128. The trenches 108 horizontally extend in the second direction A2 through the channel regions of the active regions 104 and the isolation structures 106. The patterning process may include forming a patterned mask layer (not shown) over the semiconductor structure 100 through a lithography process, and then transferring trench patterns of the patterned mask layer to the active regions 104 and the isolation structure 106 through an etching process, thereby forming the trenches 108. Due to the difference in etching selectivity, portions of the trenches 108 formed in the isolation structures 106 may be deeper than portions of the trenches 108 formed in the active regions 104.

Referring to FIG. 3, a gate dielectric layer 110 is formed lining the surface of the active regions 104 exposed from the trenches 108. The gate dielectric layer 110 is made of silicon oxide and may be formed by in-situ steam generation (ISSG). In the isolation structure 106, an insulating layer 112 is formed to fill bottom portions of the trenches 108. In some embodiments, the insulating layer 112 is made of a dielectric material, such as silicon nitride (SiN), silicon oxynitride (SiON), silicon oxide (SiO), and/or combinations thereof. The insulating layers 112 may be deposited by chemical vapor deposition and/or atomic layer deposition, followed by an etch-back process.

A first gate liner 114, a first work function layer 116, a second gate liner 118, and a second work function layer 120 are sequentially formed to partially fill the trenches 108, wherein the second gate liner 118 is also referred to as a barrier layer. The first work function layer 116 fills a lower portion of the subsequently formed gate electrode, and the second work function layer 120 fills an upper portion of the subsequently formed gate electrode. Dual work function materials can reduce electric field intensity generated by the gate electrode, thereby reducing gate-induced drain leakage (GIDL). The first work function layer 116 is nested within the first gate liner 114. In some embodiments, the first gate liner 114 is made of titanium nitride (TiN), tungsten nitride (WN), and/or tantalum nitride (TaN). In some embodiments, the first work function layer 116 is made of a metal material, such as tungsten (W), aluminum (Al), copper (Cu), cobalt (Co), or ruthenium (Ru). The materials for the first gate liner 114 and the first work function layer 116 may be deposited by physical vapor deposition (PVD), chemical vapor deposition (CVD), and/or atomic layer deposition (ALD), and then are etched back.

The second gate liner 118 is formed over the first gate liner 114 and the first work function layer 116. The first gate liner 114 and the second gate liner 118 together enclose the first work function layer 116 to prevent the material of the first work function layer 116 (e.g., tungsten) from diffusing into the gate dielectric layer 110. In some embodiments, the second gate liner 118 is made of titanium nitride (TiN), tungsten nitride (WN), and/or tantalum nitride (TaN). The formation of the second gate liner 118 may include a deposition process (e.g., chemical vapor deposition process, physical vapor deposition process, and/or atomic layer deposition process), followed by an etch-back process. The second work function layer 120 is made of polysilicon. The formation of the second work function layer 120 may include a deposition process (e.g., chemical vapor deposition process) followed an etch-back process.

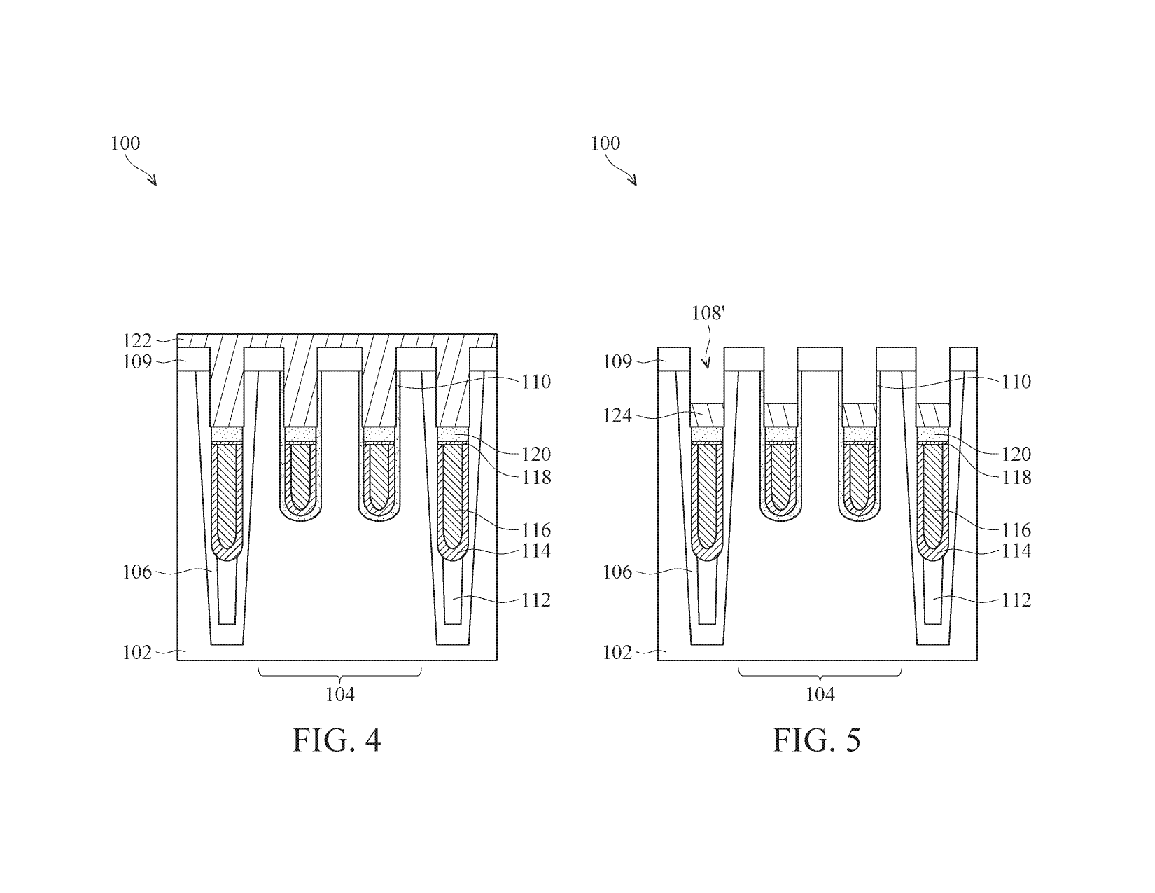

Referring to FIG. 4, a metal material 122 is deposited over the semiconductor structure 100 to overfill remaining portions of the trenches 108. In some embodiments, the metal material 122 may be tungsten (W), aluminum (Al), copper (Cu), cobalt (Co), ruthenium (Ru), metal nitride (e.g., titanium nitride (TiN), tungsten nitride (WN), tantalum nitride (TaN)), and/or other metal materials. The deposition process may be a chemical vapor deposition process, a physical vapor deposition process, and/or an atomic layer deposition process.

Referring to FIG. 5, an etching process is performed to recess the metal material 122. Upper portions of the trenches 108 are formed again and referred to as 108’. The recessed metal material 122 forms a metal capping layer 124. The etching process may be a wet etching process or a dry etching process.

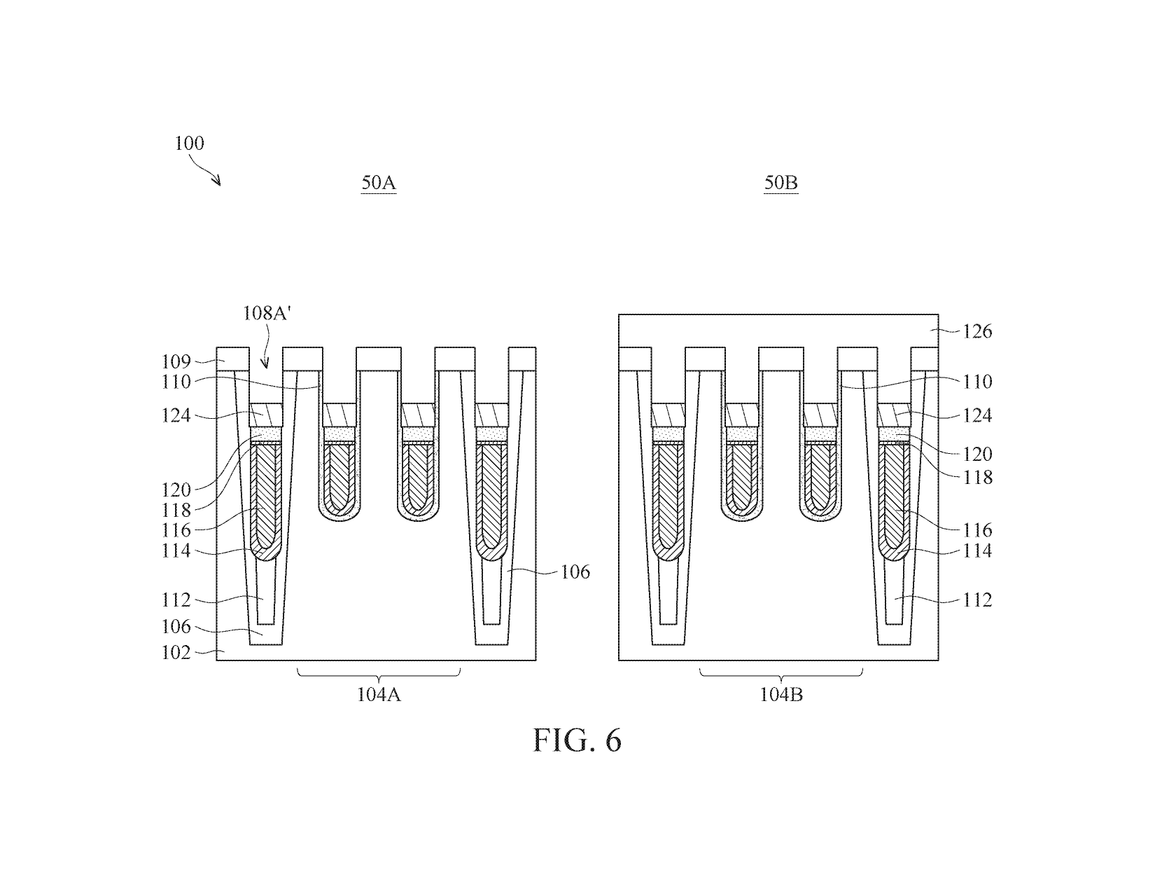

Referring to FIG. 6, the semiconductor structure 100 may include a first region 50A and a second region 50B. The semiconductor structure 100 in the first region 50A functions as a functional circuit, which may be within a die region of the wafer. The second region 50B is a test region, and the semiconductor structure 100 in the second region 50B functions as a test structure. The test structure may be located within a test region that is disposed in some die regions or in all of the die regions, within a scribe line between the die regions, and/or within the single die region dedicated to testing. After the manufacturing process of the semiconductor memory device is completed, a wafer cutting process may be performed along the scribe line to obtain individual dies. For example, the semiconductor structure 100 in the second region 50B may be configured as a test element group (TEG) and/or a test key in the test region for wafer testing during the manufacturing of the semiconductor memory device. In other embodiments, the second region 50B serves as a test structure of a module test key and may be independently defined as a single die region. The semiconductor structures 100 of the first region 50A and the second region 50B may have the same configuration as shown in FIG. 1. The active regions104 formed in the first region 50A and the second region 50B are respectively referred to as 104A and 104B.

A patterned mask layer 126 is formed to cover the semiconductor structure 100 in the second region 50B and to overfill the trenches 108’ in the second region 50B. The patterned mask layer 126 may be a patterned photoresist layer or a patterned hard mask layer. The patterned mask layer 126 may be formed through a lithography process. The patterned mask layer 126 exposes the semiconductor structure 100 in the first region 50A. The trenches 108’ in the first region 50A is referred to as 108A’.

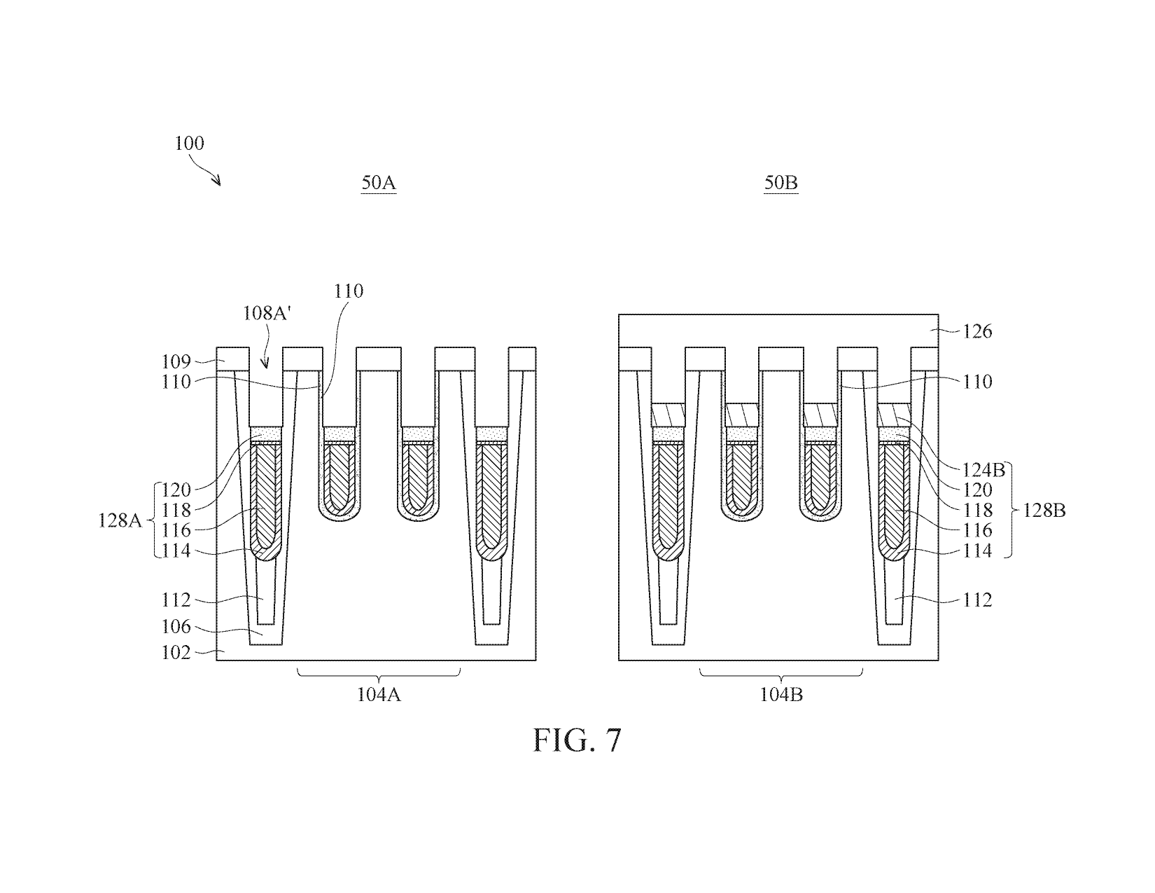

Referring to FIG. 7, an etching process is performed on the semiconductor structure 100 using the patterned mask layer 126 to remove the metal capping layer 124 in the first region 50A until the second work function layer 120 is exposed. The etching process may be a wet etching process or a dry etching process. The metal capping layer 124 remaining in the second region 50B is referred to as 124B.

In the first region 50A, the first gate liner 114, the first work function layer 116, the second gate liner 118, and the second work function layer 120 together serve as a gate electrode 128A. In the second region 50B, the first gate liner 114, the first work function layer 116, the second gate liner 118, the second work function layer 120, and the metal capping layer 124B together serve as a gate electrode 128B. The gate electrode 128A and the gate dielectric layer 110 form a gate structure. The gate structure may be configured as a word line of the obtained semiconductor memory device, such as a buried word line (BWL).

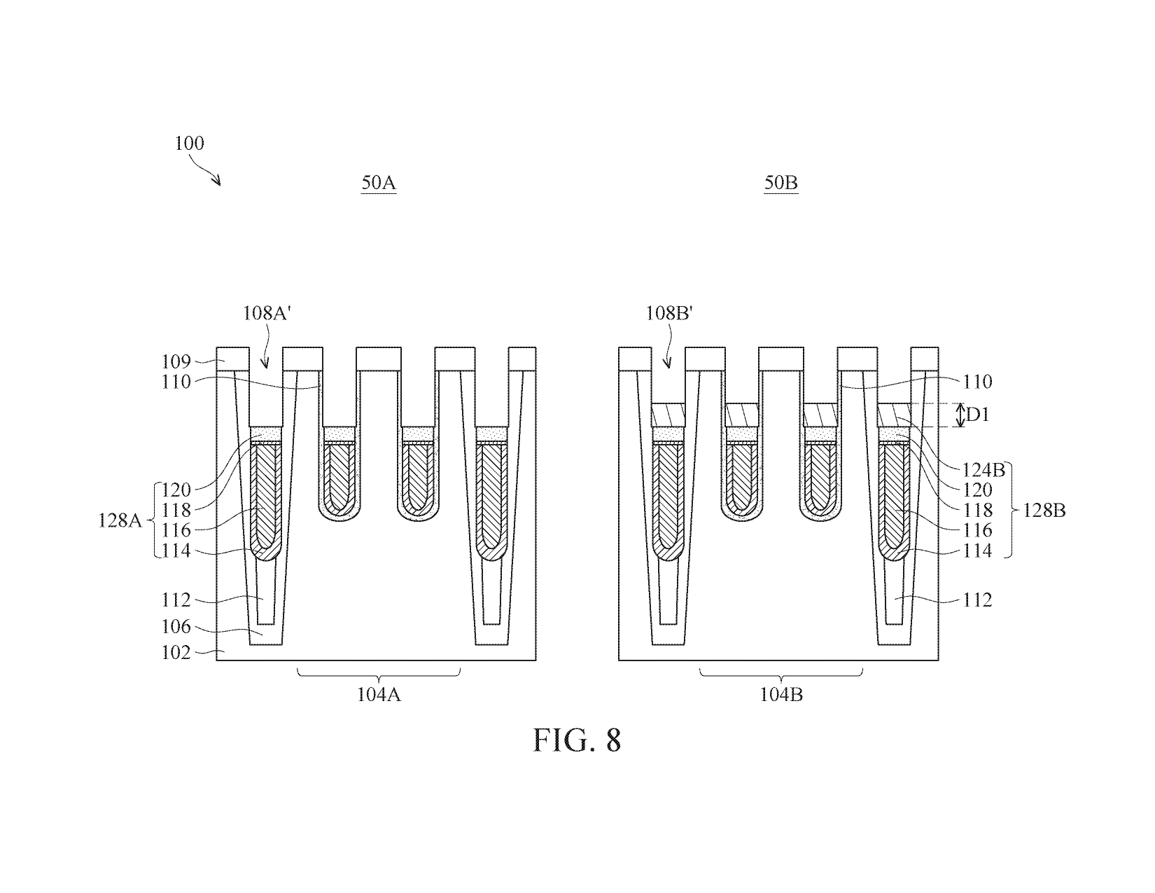

Referring to FIG. 8, the patterned mask layer 126 is removed to expose the metal capping layer 124B in the second region 50B, for example, by using an etching process, an ashing process, and/or a wet stripping process. The trenches 108’ in the second region 50B are formed again and referred to as 108B’. The metal capping layer 124B is configured to provide information of yield defects in subsequent optical inspection. In some embodiments, the metal capping layer 124B has a thickness D1 ranging from about 15 nm to about 25 nm.

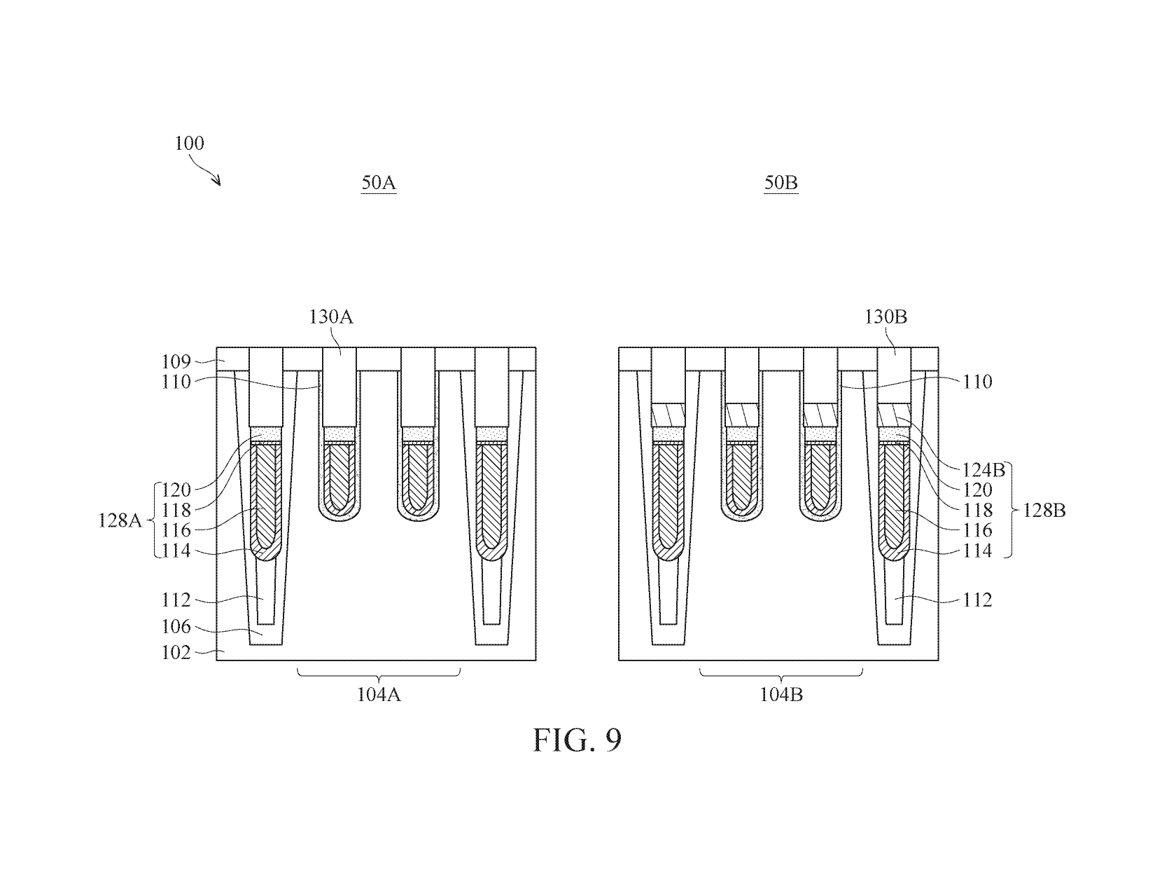

Referring to FIG. 9, a dielectric capping layer 130A and a dielectric capping layer 130B are formed to respectively fill the trench 108A’ and the trench 108B’. The dielectric capping layer 130A and the dielectric capping layer 130B are made of dielectric materials, such as silicon nitride (SiN), silicon oxide (SiO), silicon oxynitride (SiON), and/or combinations thereof. The formation of the dielectric capping layer 130A and the dielectric capping layer 130B may include a deposition process (e.g., chemical vapor deposition process and/or atomic layer deposition process) followed by a planarization process (e.g., etch-back and/or chemical mechanical polishing). The bottom surface of the dielectric capping layer 130A is lower than the bottom surface of the dielectric capping layer 130B.

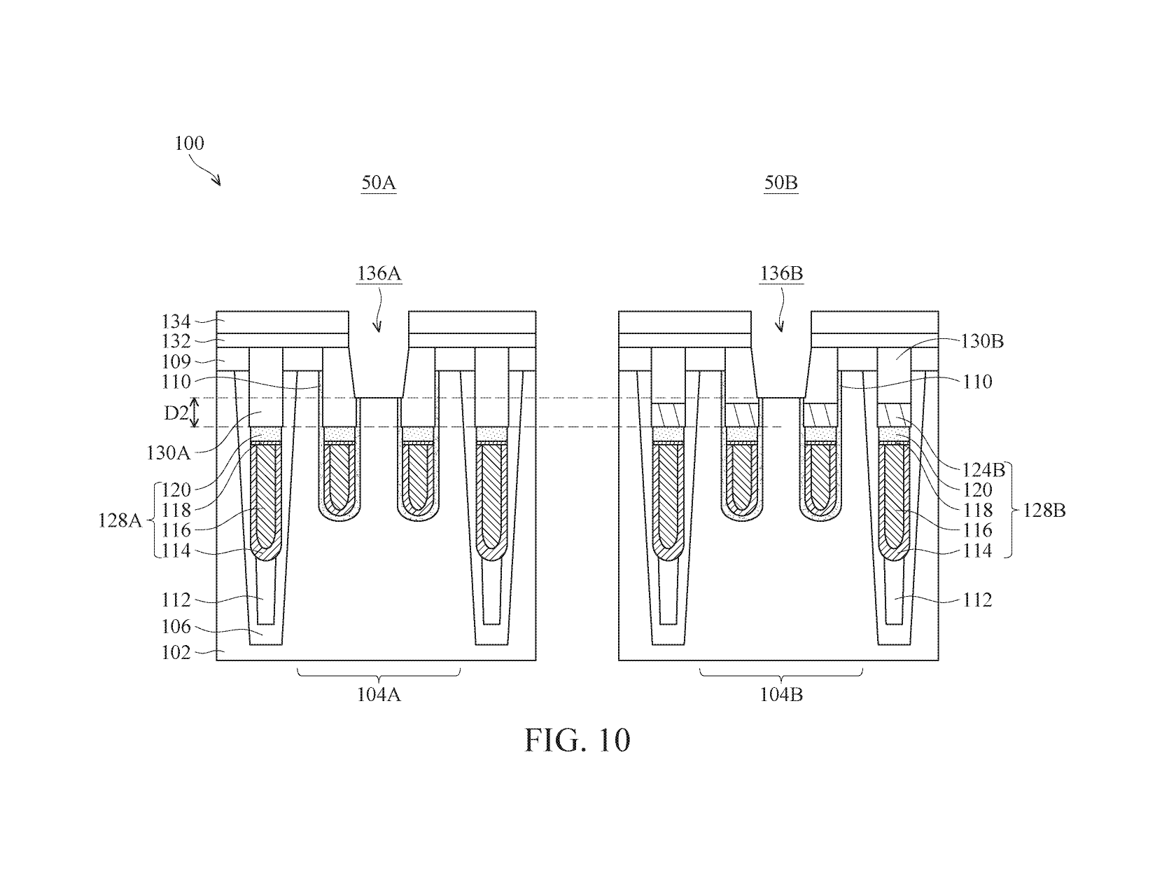

Referring to FIG. 10, mask layers 132 and 134 are formed over the semiconductor structure 100. The mask layer 132 and the mask layer 134 may be made of dielectric materials, such as silicon nitride (SiN), silicon oxide (SiO), silicon oxynitride (SiON), and/or combinations thereof. The mask layer 132 and the mask layer 134 may be formed of different dielectric materials. A patterning process is performed on the semiconductor structure 100 to respectively form an opening 136A and an opening 136B in the first region 50A and in the second region 50B. The opening 136A and the opening 136B respectively correspond to the first source/drain region of the active region 104A and the first source/drain region of the active region 104B. The patterning process may include a lithography process and an etching process (e.g., wet etching process or dry etching process).

During the etching process, the dielectric capping layer 130A in the active region 104A and the dielectric capping layer 130B in the active region 104B are recessed. In some embodiments, the bottom of the opening 136A is higher than the top surface of the second work function layer 120 of the gate electrode 128A, and the bottom of the opening 136B is higher than the top surface of the metal capping layer 124B of the gate electrode 128B. In other words, the distance D2 between the opening 136A (or 136B) and the top surface of the second work function layer 120 of the gate electrode 128A (or 128B) is greater than the thickness D1 of the metal capping layer 124B.

After the etching process, a cleaning process is performed on the semiconductor structure 100 to remove residues, etching by-products, and/or oxides on the semiconductor structure 100. When the bottom of the opening 136A is too close to the top surface of the second work function layer 120, the risk of leakage between a contact portion of a subsequently formed wiring structure 142 and the gate electrode 128A increases, thereby reducing the manufacturing yield of the semiconductor memory device. Therefore, after the cleaning process, an optical inspection is performed on the test element group in the second region 50B to analyze whether defects are present due to the metal capping layer 124B being hollowed out during the cleaning process, thereby identifying whether the depth of the opening 136A exceeds a desired value.

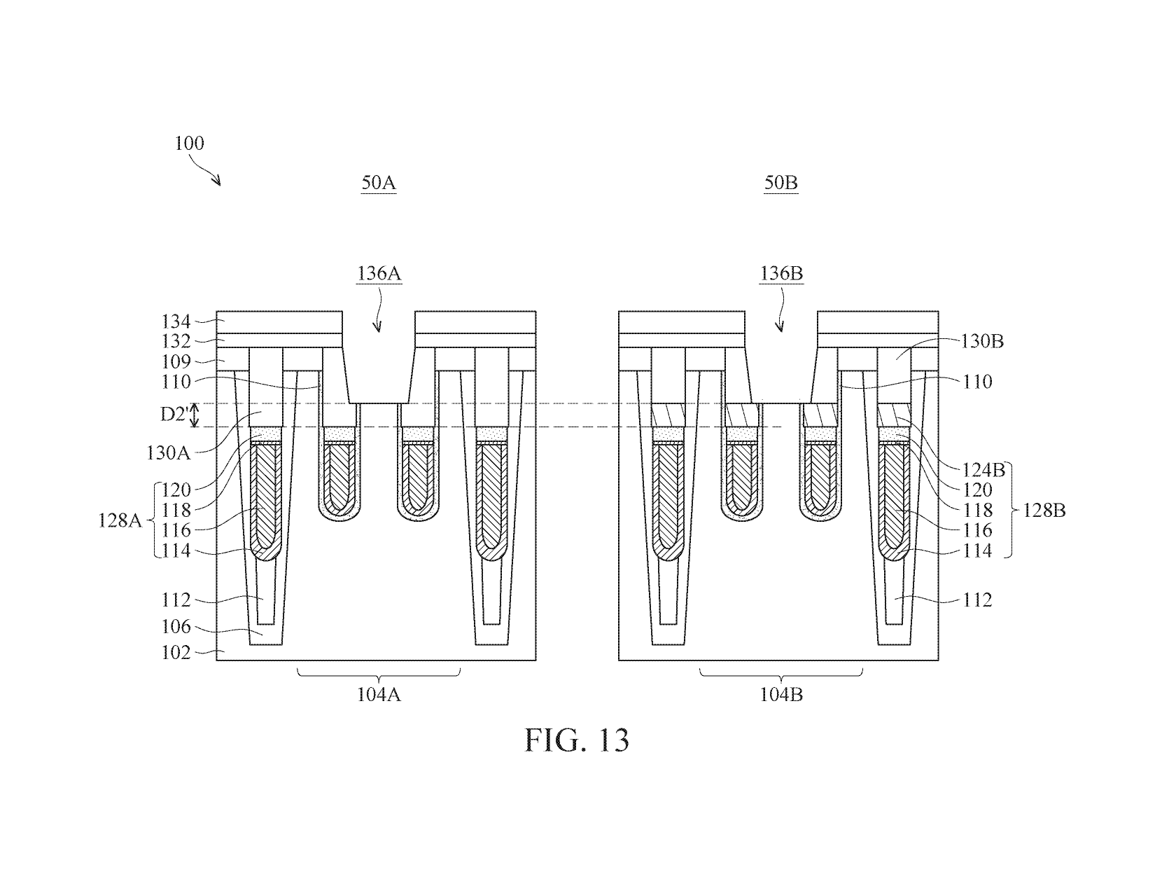

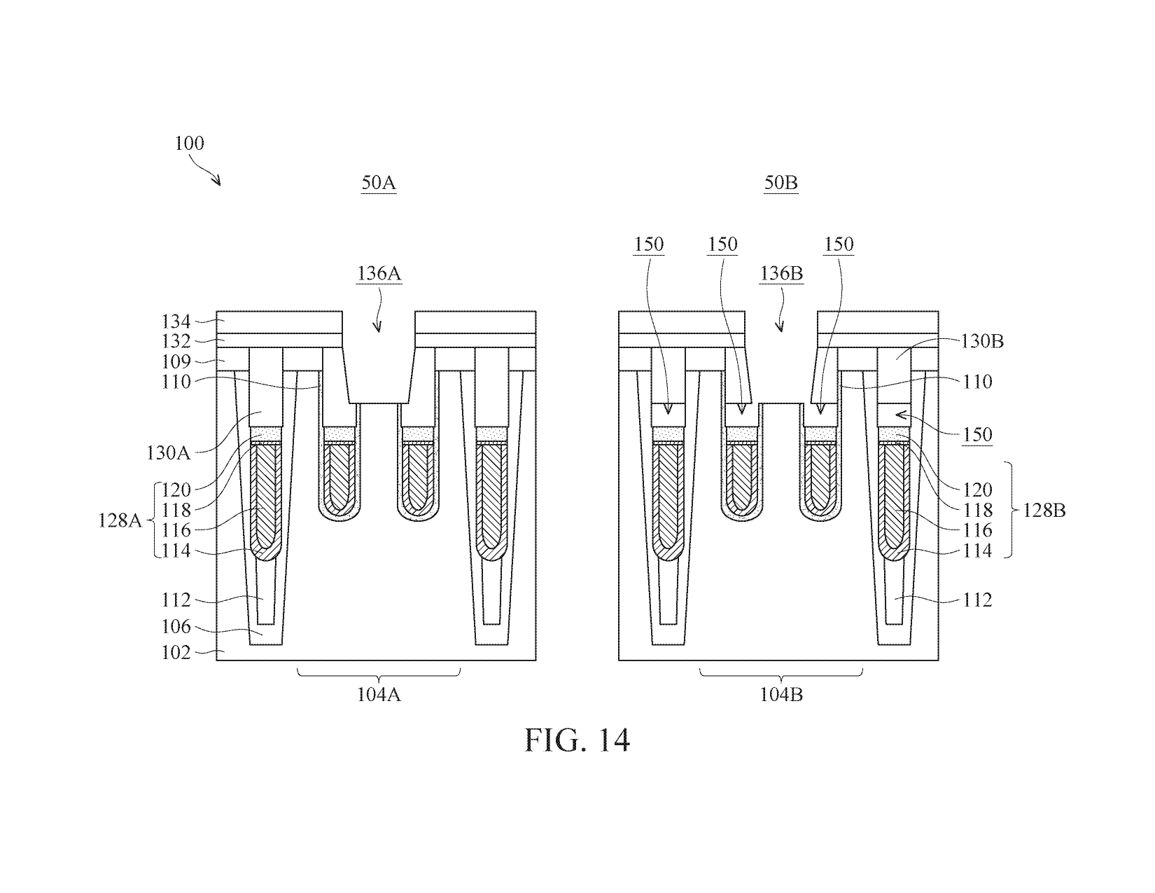

For example, referring to FIG. 13, when the depth of the opening 136A and the depth of the opening 136B exceed the desired value, the metal capping layer 124B in the second region 50B is exposed from the opening 136B. In other words, a distance D2’ between the opening 136A (or 136B) and the top surface of the second work function layer 120 of the gate electrode 128A (or 128B) is equal to or less than the thickness D1 of the metal capping layer 124B. The metal capping layer 124B is then removed to form a void 150 during the cleaning process, as shown in FIG. 14.

Since a metal material is more likely to be removed in a cleaning process to form a defect (i.e., the void 150) compared to a semiconductor material and a dielectric material, the formation of the metal capping layer 124B helps obtain information on the number and distribution of yield defects on the wafer based on the optical inspection result of the opening 136B, thereby indirectly determining whether the depth of the opening 136A in the first region 50A exceeds the desired value. In this way, wafers with the number of defects exceeding an engineering specification can be reworked or scrapped during the manufacturing stage of the semiconductor memory device, thereby reducing manufacturing cost and increasing the manufacturing yield of the semiconductor memory device.

If the thickness D1 of the metal capping layer 124B is too small, yield defects may not be detected, thereby reducing the manufacturing yield. Conversely, if the thickness D1 of the metal capping layer 124B is too large, non-yield defects may be excessively inspected, thereby increasing the manufacturing cost.

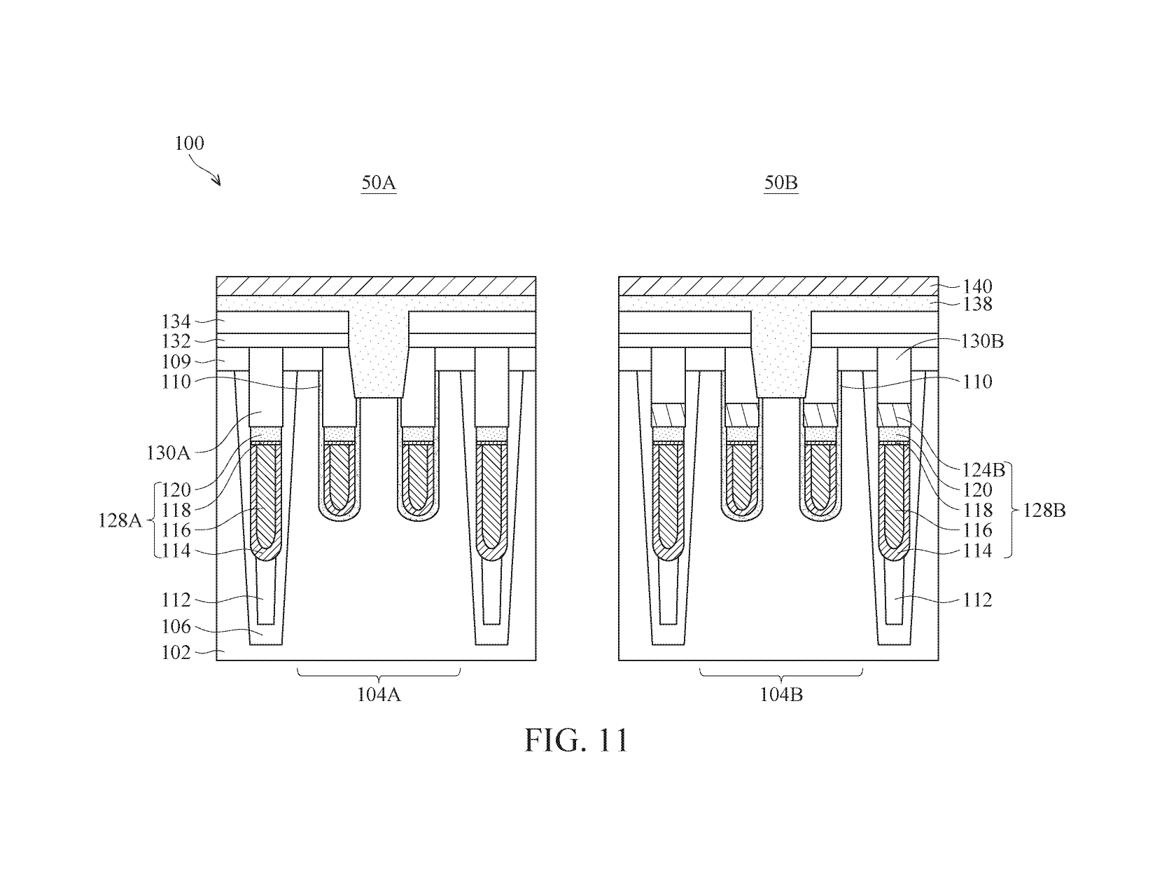

Referring to FIG. 11, a first conductive layer 138 and a second conductive layer 140 are sequentially deposited over the semiconductor structure 100. The first conductive layer 138 fills the openings 136A and 136B. The first conductive layer 138 is made of doped or undoped polysilicon. The second conductive layer 140 is made of a metal material, such as titanium nitride (TiN), tungsten nitride (WN), tantalum nitride (TaN), tungsten (W), aluminum (Al), copper (Cu), cobalt (Co), ruthenium (Ru), and/or combinations thereof. A silicide layer may be formed between the first conductive layer 138 and the second conductive layer 140.

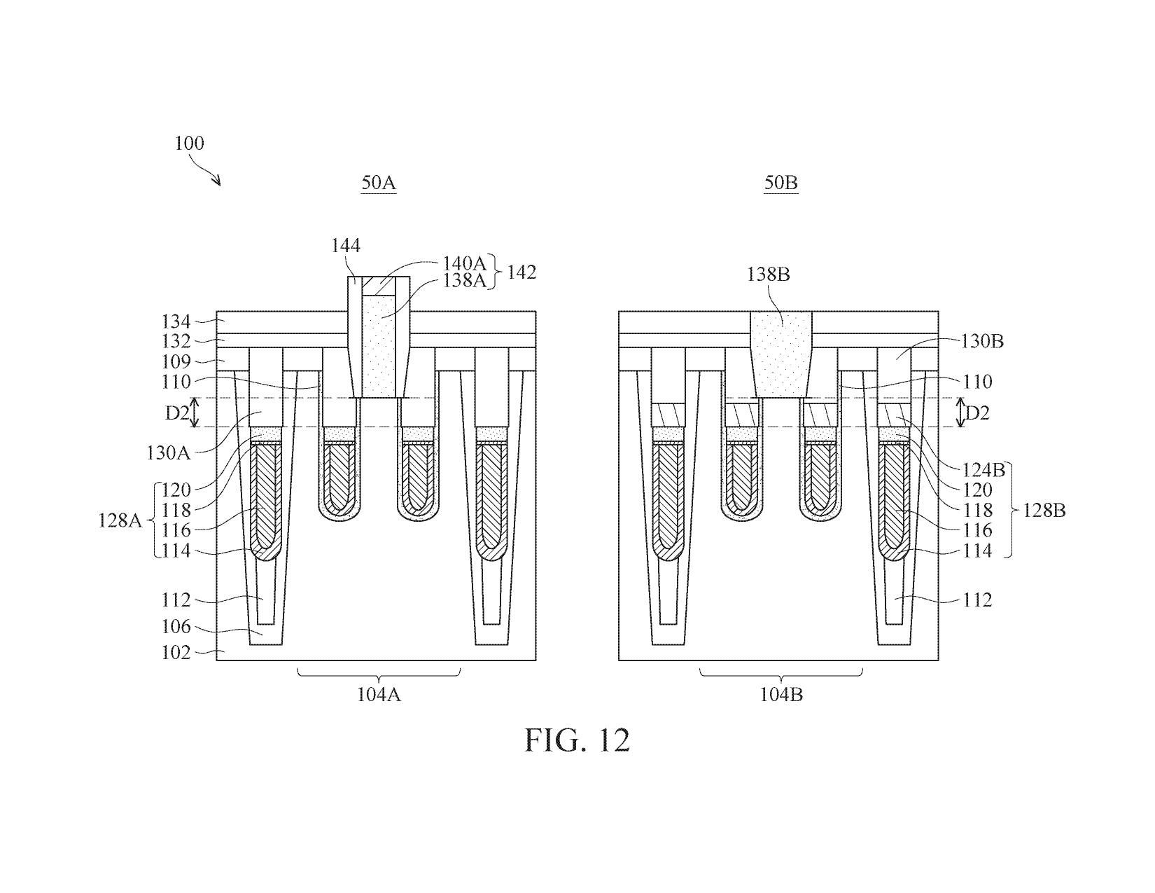

Referring to FIG. 12, a patterning process is performed on the second conductive layer 140 and the first conductive layer 138 to form the wiring structure 142 in the first region 50A. The wiring structure 142 includes a second conductive layer 140A and a first conductive layer 138A, and the wiring structure 142 is configured as the bit line of the obtained semiconductor memory device. The patterning process may include a lithography process and an etching process (e.g., wet etching process or dry etching process). A portion of the first conductive layer 138 in the opening 136A serves as a contact portion of the wiring structure 142. The contact portion lands on the first source/drain region of the active region 104.

In the second region 50B, the patterning process may remove the second conductive layer 140 and the first conductive layer 138 outside of the opening 136B. A portion of the first conductive layer 138 in the opening 136B is referred to as 138B. In other embodiments, the patterning process may form the wiring structure 142 in the second region 50B that is similar to that in the first region 50A. In still other embodiments, the second conductive layer 140 and the first conductive layer 138 in the second region 50B may be removed, and then other materials may be filled into the opening 136B.

Spacer layers 144 are formed on opposite sides of the wiring structure 142 and fills a remaining portion of the opening 136A. The spacer layers 144 are made of one or more dielectric materials, such as silicon oxide (SiO), silicon nitride (SiN), silicon oxynitride (SiON), and/or combinations thereof. Additional components may be formed over the semiconductor structure 100 shown in FIG. 12, thereby obtaining the semiconductor memory device. For example, a contact plug, a contact pad, a capacitor structure and/or other applicable components may be formed on the second source/drain region. In some embodiments, the semiconductor memory device is a dynamic random access memory (DRAM).

Embodiments of the present disclosure also provide an inspection method for a semiconductor structure. The inspection process may obtain information on the number of the voids 150 in the test region (the second region 50B) and the distribution of the voids 150 on the wafer. Through this information on the number and distribution of voids 150, information on the number and distribution of undesired openings 136A in the die region can be indirectly obtained, thereby determining whether the number and distribution of undesired openings 136A fall outside the engineering specification. In some embodiments, after the aforementioned cleaning process, an inspection process is performed on the semiconductor structure 100. In some embodiments, the semiconductor substrate 102 may be positioned under an inspector used for inspecting to perform an imaging operation.

The detector may scan the semiconductor substrate 102 with a light source to detect the surface roughness, the surface morphology, or the surface defect of the semiconductor substrate 102. The detector may include an optical microscope (OM) and an electron microscope (e.g., a scanning electron microscope (SEM), a transmission electron microscope (TEM), and the like). In addition, the detector further includes a camera to capture an image of the semiconductor substrate 102. For example, the detector may identify coordinates, alignment, or orientation of the semiconductor substrate 102 and linearly scan the surface of the semiconductor substrate 102 to generate a surface defect distribution map. A signal of the second region 50B (e.g., a test region or a test key) may be compared with a signal of the first region 50A (e.g., a die region) to determine whether a defect exists. Some test regions of the wafer have voids 150 (as shown in FIG. 14), while other test regions of the wafer do not have voids 150 (as shown in FIG. 10). A surface defect distribution map may be obtained, which provides information on the number of the voids 150 and the location of the voids 150 on the semiconductor substrate 102 (e.g., coordinates). In this way, the degree and distribution of the openings 136A having the depth exceeding the expected value can be indirectly determined.

Next, a data computing system is used to analyze the information on the voids 150 in the surface defect distribution map to perform a determination operation. The information on the number and the coordinates of the voids 150 is compared with the engineering specification stored in the data computing system to determine whether the number of the voids 150 falls within the engineering specifications, and thus indirectly determining whether the number of openings 136A having the depth exceeding the expected value falls within the engineering specification. In some embodiments, an algorithm may be used to analyze whether the distribution of the voids 150 matches a specific pattern stored in the data computing system. When the number of the voids 150 falls within the engineering specification, the semiconductor structure 100 subsequently undergoes further manufacturing processes. When the number of the voids 150 falls outside the engineering specification, the manufacturing process is directed to rework or scrap the wafer.

Based on the foregoing, embodiments of the present disclosure relate to the test element group of the dynamic random access memory. The test element group includes the metal capping layer 124B. When the depth of the opening 136B exceeds the expected value, the metal capping layer 124B may be easily removed during the cleaning process. In this way, information on the number and the distribution of yield defects on the wafer can be accurately obtained, thereby indirectly obtaining the condition of the openings 136A having the depths exceeding the expected value. Wafers having a number of defects exceeding the engineering specification are reworked or scrapped, thereby reducing the manufacturing cost of the semiconductor memory device and improving the manufacturing yield of the semiconductor memory device.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A semiconductor structure, comprising:
a first active region in a first region of a semiconductor substrate;
a first gate electrode in the first active region, wherein the first gate electrode comprises:
a first work function layer filling a lower portion of the first gate electrode;
a second work function layer over the first work function layer and filling an upper portion of the first gate electrode;
a first barrier layer between the first work function layer and the second work function layer; and
a metal capping layer over the second work function layer; and
a first dielectric capping layer over the first gate electrode.

2. The semiconductor structure as claimed in claim 1, wherein the first work function layer is made of a metal material, and the second work function layer is made of a semiconductor material.

3. The semiconductor structure as claimed in claim 1, wherein the metal capping layer is made of a metal nitride.

4. The semiconductor structure as claimed in claim 1, further comprising: a gate dielectric layer disposed between the first gate electrode and the first active region, wherein the gate dielectric layer is in direct contact with the first barrier layer, the second work function layer, and the metal capping layer of the first gate electrode.

5. The semiconductor structure as claimed in claim 1, wherein a thickness of the metal capping layer ranges from about 15 nm to about 25 nm.

6. The semiconductor structure as claimed in claim 1, further comprising:
a second active region in a second region of the semiconductor substrate;
a second gate electrode in the second active region, wherein the second gate electrode comprises:
a third work function layer;
a fourth work function layer over the third work function layer; and
a second barrier layer between the third work function layer and the fourth work function layer; and
a second dielectric capping layer over the second gate electrode, wherein a bottom surface of the second dielectric capping layer is lower than a bottom surface of the first dielectric capping layer.

7. The semiconductor structure as claimed in claim 6, wherein the metal capping layer of the first gate electrode is in direct contact with the first dielectric capping layer, and the fourth work function layer of the second gate electrode is in direct contact with the second dielectric capping layer.

8. The semiconductor structure as claimed in claim 6, wherein the first region is a test region of the semiconductor substrate and the second region is a die region of the semiconductor substrate.

9. The semiconductor structure as claimed in claim 6, further comprising:
a wiring structure over the second active region, wherein the second gate electrode extends in a first horizontal direction, and the wiring structure extends in a second horizontal direction perpendicular to the first horizontal direction.

10. The semiconductor structure as claimed in claim 1, further comprising:
a semiconductor material extending into the first active region, wherein the semiconductor material and the metal capping layer of the first gate electrode are spaced apart by the first dielectric capping layer.

11. The semiconductor structure as claimed in claim 1, further comprising: a gate dielectric layer between the first active region and the gate electrode layer, wherein the gate electrode layer further comprises a second barrier layer between the gate dielectric layer and the first work function layer.

12. A method for forming a semiconductor structure, comprising:
forming a first active region and a second active region;
forming a first trench in the first active region and forming a second trench in the second active region;
forming a first work function layer in the first trench and the second trench;
forming a second work function layer over the first work function layer in the first trench and the second trench to form a first gate electrode, wherein the first work function layer fills a lower portion of the first gate electrode, and the second work function layer fills an upper portion of the first gate electrode;
forming a metal material over the second work function layer in the first trench and the second trench;
removing a first portion of the metal material in the first trench, wherein a second portion of the metal material remaining in the second trench forms a metal capping layer; and
forming a first dielectric capping layer on the second work function layer in the first trench and forming a second dielectric capping layer on the metal capping layer in the second trench.

13. The method as claimed in claim 12, wherein the step of removing the first portion of the metal material in the first trench comprises:
forming a patterned mask layer covering the second portion of the metal material; and
etching the first portion of the metal material.

14. The method as claimed in claim 12, further comprising:
forming a barrier layer over the first work function layer in the first trench and the second trench, wherein the second work function layer is formed over the barrier layer.

15. The method as claimed in claim 12, further comprising:
performing a patterning process on the first active region and the second active region to form a first opening and a second opening, respectively; and
performing a cleaning process after the patterning process.

16. The method as claimed in claim 15, further comprising:
forming a conductive material to fill the first opening and the second opening; and
patterning the conductive material to form a bit line over the first active region.

17. The method as claimed in claim 12, wherein the first active region is formed in a die region of a semiconductor substrate, and the second active region is formed in a test region of the semiconductor substrate.

18. An inspection method, comprising:
receiving a semiconductor structure, the semiconductor structure comprising test regions and die regions disposed on a semiconductor substrate, wherein each of the test regions and the die regions comprises a gate electrode embedded in the semiconductor substrate, a dielectric capping layer disposed over the gate electrode and partially embedded in the semiconductor substrate, and an opening over the semiconductor substrate and exposing a sidewall of the dielectric capping layer, wherein the gate electrode comprises a first work function layer filling a lower portion of the gate electrode, a second work function layer over the first work function layer and filling an upper portion of the gate electrode, and a barrier layer between the first work function layer and the second work function layer;
performing an imaging operation on the test regions of the semiconductor structure to generate a surface defect distribution map, wherein the surface defect distribution map has information indicating whether a void exists between the dielectric capping layer and the second work function layer; and
performing a determination operation on the surface defect distribution map to determine whether depths of the openings in the functional circuit regions exceed an expected value.

19. The method as claimed in claim 18, wherein the test regions are divided into a first group and a second group, each of the test regions in the first group has the void, and each of the test regions in the second group further comprises a metal capping layer between the dielectric capping layer and the second work function layer.

20. The method as claimed in claim 19, wherein:
in the first group, the void is in communication with the opening; and
in the second group, a bottom end of the opening is higher than a top surface of the metal capping layer.
